(19) United States
(12) Patent Application Publication
(10) Pub. No.: US 2018/0373143 A1
(43) Pub. Date: Dec. 27, 2018

(54) SENSITIVITY ENHANCED PHOTORESISTS

(71) Applicant: Irresistible Materials LTD, Swansea (GB)

(72) Inventors: Alex Phillip Graham Robinson, Birmingham (GB); Andreas Frommhold, Dera (DE); John Roth, Cohasset, MA (US)

(73) Assignee: Irresistible Materials LTD, Swansea (GB)

(21) Appl. No.: 15/136,828

(22) Filed: Apr. 22, 2016

(51) Int. Cl. G03F 7/004; G03F 7/027; G03F 7/039; G03F 7/038

(52) U.S. Cl. CPC G03F 7/0045; G03F 7/0382; G03F 7/0392; G03F 7/027

(57) ABSTRACT

The present disclosure relates to novel positive and negative photoresist compositions containing components that are based on one or more specific metals, metal salts, and/or metal complexes and methods of using them. The photoresist compositions and the methods are ideal for high speed, fine pattern processing using, for example, ultraviolet radiation, extreme ultraviolet radiation, beyond extreme ultraviolet radiation, X-rays, electron beam and other charged particle rays. The metals are characterized by high absorption cross sections and selected elastic and inelastic electron cross section.

### FIELD OF INVENTION

The present disclosure relates to novel positive and negative photoresist compositions containing ingredients that are based on specific metals and methods of using them. The photoresist compositions and the methods are ideal for high speed, fine pattern processing using, for example, ultraviolet radiation, extreme ultraviolet radiation, beyond extreme ultraviolet radiation, X-rays, electron beam and other charged particle rays.

### REFERENCE TO PRIOR FILED APPLICATION

The present application claims the benefit under 35 U.S.C. 119(e), of U.S. provisional patent application Ser. No. 62/1651,364 filed on 22 Apr. 2015, entitled “Sensitivity Enhanced Photoresist” which application is incorporated by reference herein in its entirety.

### BACKGROUND

As is well known, the manufacturing process of various kinds of electronic or semiconductor devices such as ICs, LSIs and the like involves a fine patterning of a resist layer on the surface of a substrate material such as a semiconductor silicon wafer or on wafers that contain additional layers. This fine patterning process has traditionally been conducted by the photolithographic method in which the substrate surface is uniformly coated with a positive or negative tone photoresist composition to form a thin layer of thephotoresist composition and selectively irradiating with actinic rays (such as ultraviolet light) through a photomask followed by a development treatment to selectively dissolve away the photoresist layer in the areas exposed, positive resist, or unexposed, negative resist, to the actinic rays leaving a patterned resist layer on the substrate surface. The thusobtained patterned resist layer can be utilized as a mask in subsequent treatments on the substrate surface such as etching, plating, self-assembly processes and the like. The fabrication of structures with dimensions on the order of nanometers is an area of considerable interest since it enables the realization of electronic and optical devices, which exploit novel phenomena such as quantum confinement effects and also allows greater component packing density. As a result, the resist layer is required to have an ever increasing fineness which can be accomplished by methods such as by using actinic rays having a shorter wavelength than the conventional ultraviolet light. Accordingly, it is now the case that, in place of the conventional ultraviolet light, electron beams (e-beams) excimer laser beams, EUV, BEUV and X-rays are used as the short wavelength actinicrays. The minimum size obtainable is primarily determined by the performance of the resist material and the wavelength of the actinic rays. Various materials have been proposed as suitable resist materials to obtain these fine features. In the case of negative tone resists based on polymer crosslinking, there is an inherent resolution limit of about 10 nm, which is the approximate radius of a single polymer molecule.

It is also known to apply a technique called “chemical amplification” to the polymeric resist materials. A chemically amplified resist material is generally a multi-component formulation in which there is a main polymeric component, such as a novolac resin which contributes towards properties such as resistance of the material to etching and its mechanical stability and one or more additional components which impart desired properties to the resist and a sensitizer. By definition, the chemical amplification occurs through a catalytic process involving the sensitizer, which results in a single irradiation event causing exposure of multiple resist molecules. In a typical example the resist comprises a polymer and a photoacid generator (PAG) as sensitizer. The PAG releases aproton in the presence of radiation (light or e-beam), either directly or via a process mediated via other components in the resist. Such processes, for example, as in EUV and Ebeam exposures where the photon/electron typically interacts with the polymer or crosslinker, to generate a radical which then interacts with the PAG to create a proton.

This proton can then for example react with the polymer to cause it to lose a functional group, or cause crosslinking to occur. In the process, a second proton is generated which can then react with a further molecule. The speed of the reaction can be controlled, for example, by heating the resist film to drive the reaction. After heating, the reacted polymer molecules are free to react with remaining components of the formulation, as would be suitable for a negative-tone resist. In this way the sensitivity of the material to actinic radiation is greatly increased, as small numbers of irradiation events give rise to a large number of exposure events.

In such chemical amplification schemes, irradiation results in cross-linking of the exposed resist material, thereby creating a negative tone resist. The polymeric resist material may be self-cross-linking or a cross linking molecule may be included. Chemical amplification of polymeric-based resists is disclosed in U.S. Pat. Nos. 5,968,712, 5,529,885, 5,981,139 and 6,607,870.

Various fullerene derivatives have been shown to be useful e-beam resist materials by the present inventors, Appl. Phys. Lett. volume 72, page 1302 (1998), Appl. Phys. Lett. volume 312, page 469 (1999), Mat. Res. Soc. Symp. Proc. volume 546, pace 219 (1999) and U.S. Pat. No. 6,117,617.

Additionally photogenerated acid materials can be used to interact with chosen materials which can have an acid labile group as a component, wherein the remaining material has an altered solubility in a developer such as, for example, a base containing developer. One area that is always of interest is the photospeed of photoresists. Higher photospeed means higher output, and in some cases, higher photospeed can mean improved resolution capabilities. Various methods and “tricks” have been used to increase the photospeed of both positive and negative working photoresists including addition of photocatalysts, photosensitizers and photoabsorbers.

As can be seen there is an ongoing desire to obtain finer and finer resolution of photoresists that will allow for the manufacture of smaller and smaller semiconductor devices in order to meet the requirements of current and further needs. It is also desirable to create materials, which can be used in conjunction with these photoresists, which will be more robust to the processes used to create current semiconductor devices, such as, for example, etching resistance. There is also an on-going desire to increase photospeed of lithographic photoresists.

### SUMMARY OF EXEMPLARY EMBODIMENTS

In a first embodiment, disclosed and claimed herein is a photoresist composition comprising at least one metal component wherein the metal component exhibits high EUV photoabsorption cross-section, median to high inelastic electron scattering and low to median elastic scattering coefficients.

In a second embodiment, disclosed and claimed herein is the photoresist composition of the above embodiments wherein the at least one metal is chosen from the periodic table of elements of columns 3 through 17 and rows 3 through 6, which includes Scandium, Titanium, Vanadium, Chromium, Manganese, Iron, Cobalt, Nickel, Copper, Zinc, Gallium, Germanium, Arsenic, Selenium, Bromine, Yttrium, Zirconium, Niobium, Molybdenum, Technetium, Ruthenium, Rhodium, Palladium, Silver, Cadmium, Indium, Tin, Antimony, Tellurium, Iodine, the Lanthanides, Hafnium, Tantalum, Tungsten, Rhenium, Osmium, Iridium, Platinum, Gold, Mercury, Lead, Bismuth, Polonium, and columns 13-17 row 3 which includes Aluminum, Silicon, Phosphorus, Sulfur and Chlorine.

In a third embodiment, disclosed and claimed herein are the photoresist compositions of the above embodiments wherein the at least one metal comprises a metal salt, a coordinated complex and/or a metal containing ligand.

In a fourth embodiment disclosed and claimed herein are the photoresist compositions of the above embodiments wherein the at least one metal salt comprises an oligomeric or a polymeric ligand.

In a fifth embodiment, disclosed and claimed herein are the photoresist of the above embodiments wherein the photoresist composition comprises a negative working photoresist or a positive working photoresist and has sensitivity to radiation comprising EUV radiation or has sensitivity to e-beam radiation.

In a sixth embodiment, disclosed and claimed herein are the photoresist compositions of the above embodiments wherein the at least one metal complex comprises at least one EUV stable complexing material or at least one EUV unstable complexing material.

In a seventh embodiment, disclosed and claimed herein are the photoresist compositions of the above embodiments comprising a photoacid generator

In an eighth embodiment, disclosed and claimed herein are the photoresist compositions of the above embodiments comprising at least one of a malonate, a malonate-imine adduct or a malonate-amine-imide adduct.

In a ninth embodiment, disclosed and claimed herein are the photoresist compositions of the above embodiments comprising one or more of polymers, oligomers, crosslinkers, materials with acid labile groups, materials that react with acids, solvent, acid scavengers, colorants, wetting agents, rheological agents, antifoams, fullerenes, fullerene derivatives.

In a tenth embodiment, disclosed and claimed herein are the photoresist compositions of the above embodiments wherein the metal is present in the photoresist from about 0.01% wt/wt to about 25% wt/wt.

In an eleventh embodiment, disclosed and claimed herein is a method of improving the photosensitivity of a photosensitive process by applying a photoresist composition of any of the above photoresists, removing solvent to leave less than 10% remaining, exposing the applied photoresist composition to actinic radiation or E-beam, optionally post exposure baking and removing the desired areas using a suitable developer.

### BRIEF DESCRIPTION OF THE FIGURES

FIGS. 1B through 1H are portions of the Periodic Table of the Elements with two graphs associated with each element. Looking at a particular element of the section of the Periodic Table shown, the line graph to the left depicts the relative elastic electron scattering of the element (broken line) on the y-axis when exposed to radiation from 10 eV to 100 eV on the x-axis and the inelastic electron scattering of the element (solid line) using the same axes. The bar graph on the right depicts three bars, the absorbance (left bar), photoabsorbance cross section (center bar) and inelastic electron cross section (right bar) for each element when exposed to light at 13.5 nm wavelength.

FIG. 1A is the key to the charts in FIGS. 1B-1H showing an example of the two charts associated with each element.

FIGS. 1B through 1G are arranged using the IUPAC group naming recommendation: Groups 1 through 18 and Lanthanide and Actinide periods.

FIG. 1B shows Groups 1 and 2.

FIG. 1C shows Groups 3 through 6.

FIG. 1D shows Groups 7 through 10.

FIG. 1E shows Groups 11 through 13.

FIG. 1F shows Groups 14 through 16.

FIG. 1G shows Groups 17 and 18

FIG. 1H shows the Lanthanides and the Actinides for which data is available.

FIG. 2 graphically displays the photo sensitivity of the photoresists of the current disclosure with various amounts of tin chloride added compared to the same resist without the added tin chloride.

FIG. 3 graphically displays the photo sensitivity of the photoresists of the current disclosure with 5% tin chloride added into two positive working resists compared to the same photoresists without it.

FIG. 4 graphically displays the photo sensitivity of the photoresists of the current disclosure with ruthenium, silver, iron and tin added compared to the same photoresist which was freshly made and which was aged without the added metals.

FIG. 5 graphically displays the photosensitivity of the photoresist of the current disclosure with 1% tin, ruthenium, and tetracoordinate tin added compared to the photoresist without the added metal, as well as the photoresist with tin and with lower amounts of PAG.

### DETAILED DESCRIPTION

As used herein, the conjunction “and” is intended to be inclusive and the conjunction “or” is not intended to be exclusive unless otherwise indicated. For example, the phrase “or, alternatively” is intended to be exclusive.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise. As used herein, the terms “dry”, “dried” and “dried coating” means having less than 8% residual solvent.

As used herein the term “protected polymer” means a polymer which is used in the chemical amplification process, such polymer containing acid-labile functionality so that when exposed to an acid the functionally it giving a polymer with different functionality.

As used herein the term metal includes the neutral, unoxidized species as well as any of the typical oxidation states that the metal may be in.

It has surprisingly been found that photoresists have increased photo speed when they contain the metals of the current disclosure. Not to be held to theory, it is believed that when the metal atom, metal cation, or coordinated metal or coordinated metal cation of the current disclosure is exposed to actinic radiation, such as, for example, EUV or E-beam, that secondary electrons are ejected. In photoresists, both positive and negative, that depend on photoacid generators (PAG), these secondary electrons enter into the PAG reaction scheme that generates an acid, such acid then can react with other acid sensitive component of the positive or negative photoresist. Thus exposure of the metals of the current disclosure, when they are components of a composition containing materials with acid-labile functionalities or other chemical amplification schemes, would directly enhance the production of acid, due to high levels of secondary electrons, which in theory cause the acid generator to produce more acid, whilst in a non-chemically amplified resist increased secondary electron generation would lead to increased direct exposure events. Increases of 2 to 10 times have been obtained when the compositions of the current disclosure were used.

Thus, adding a metal compound of the current disclosure to a photoresist composition can lead to a significant enhancement in the sensitivity of the material under actinic irradiation, such as, for example, EUV radiation. In some cases, the dose to size ratio, (which is a measure of photospeed, a lower number indicating that low exposure provides smaller photoresist features) of a particular photoresist composition decreased by between from about 15 to about 58% depending on the metal compound and amount added. Again, surprisingly, with some with of the metal-containing compositions, the increase in photo-sensitivity has not come at the cost of significant degradation in the line-edge roughness (LER) or the critical dimension (CD) as might normally be expected. Again, not to be held to theory it is also believed that the metal additive of the current disclosure improves the absorption of the actinic radiation and/or regeneration of secondary electrons in the film, thus improving sensitivity. Thus, the metals of the current disclosure act to pick up normally non-used radiation and channels it to the photoacid generator. The result is an increase in the efficiency of the radiation process and boosts in the effective quantum yield of the reaction.

In another aspect of the current disclosure, not to be held to theory, it is believed that some metals of the current disclosure can act as energy transfer agents. In this aspect, normally unused radiation can be absorbed by the metal and reemitted to expose the PAG to create a higher level of acid. Thus, again, there is an increase in the efficiency of the radiation process and boosts in the effective quantum yield of the reaction. In some cases, the metal can act as both an energy transfer agent and a secondary electron source, both of which will increase the apparent photo-sensitivity.

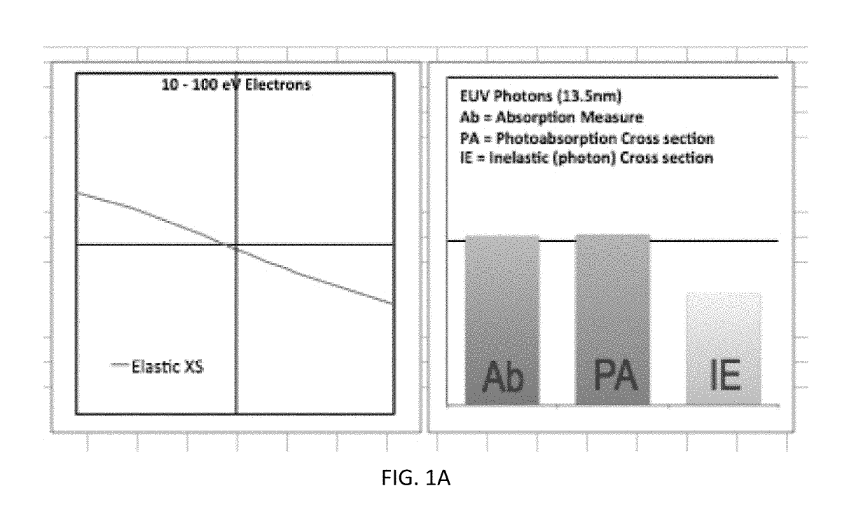

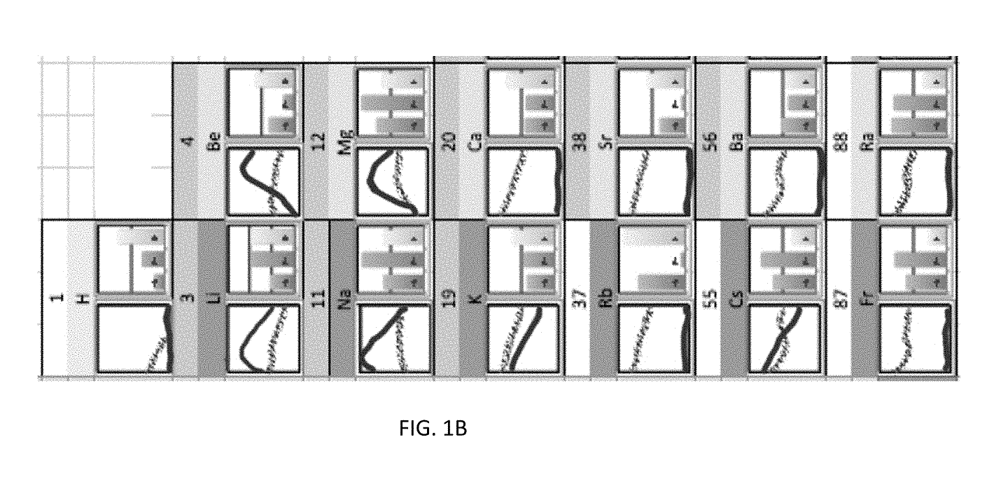

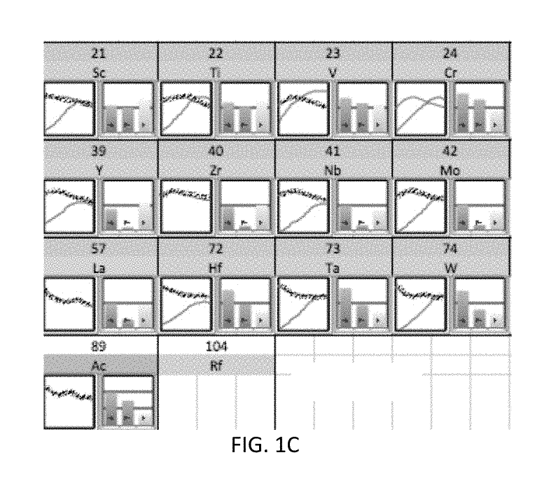

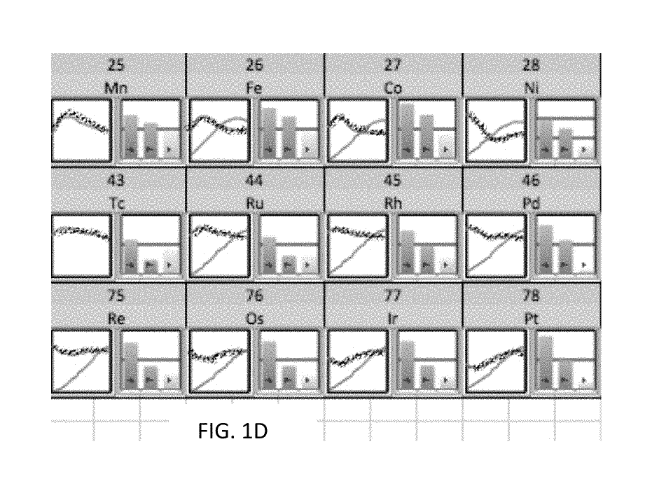

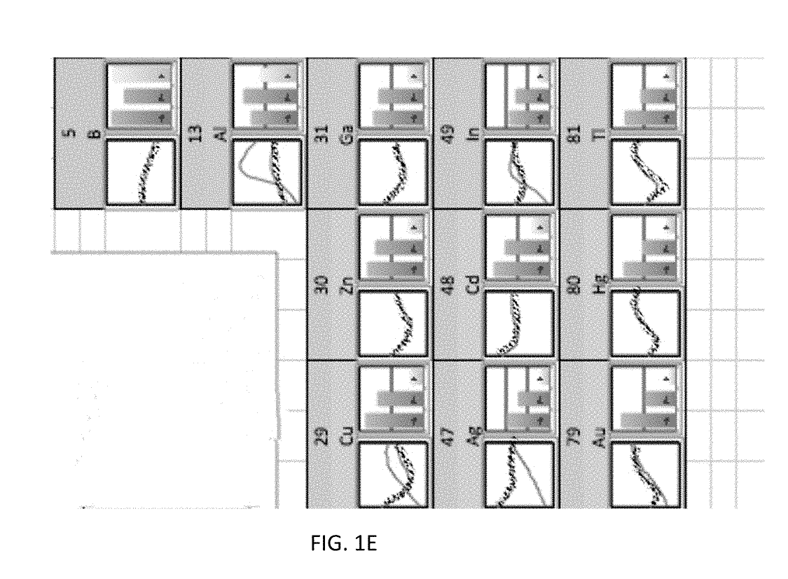

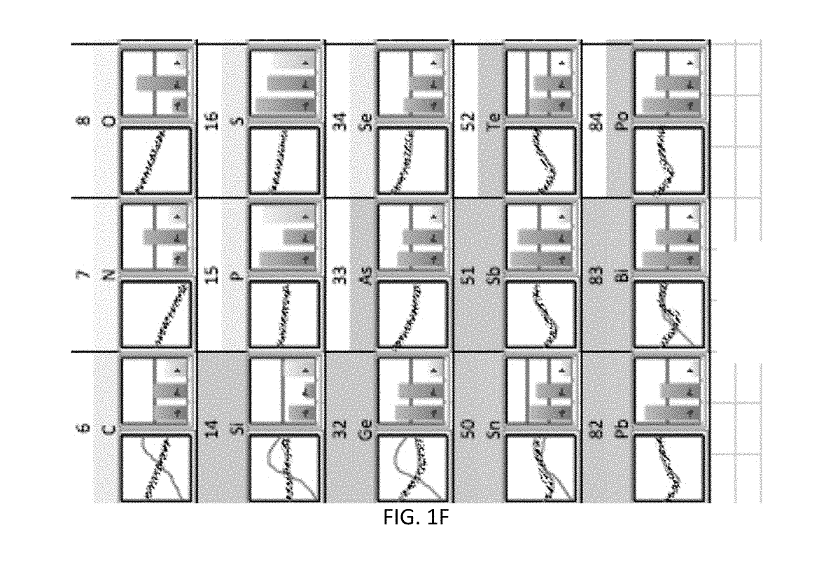

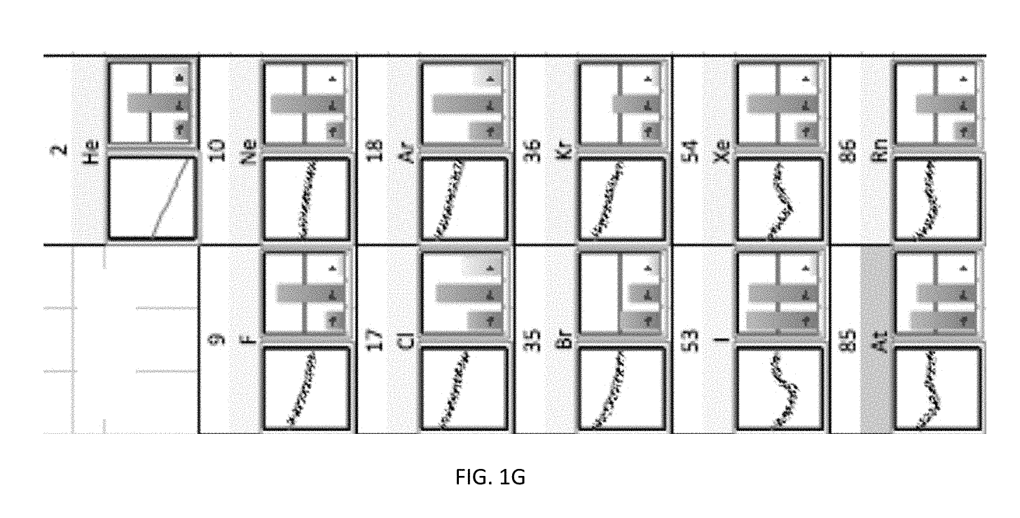

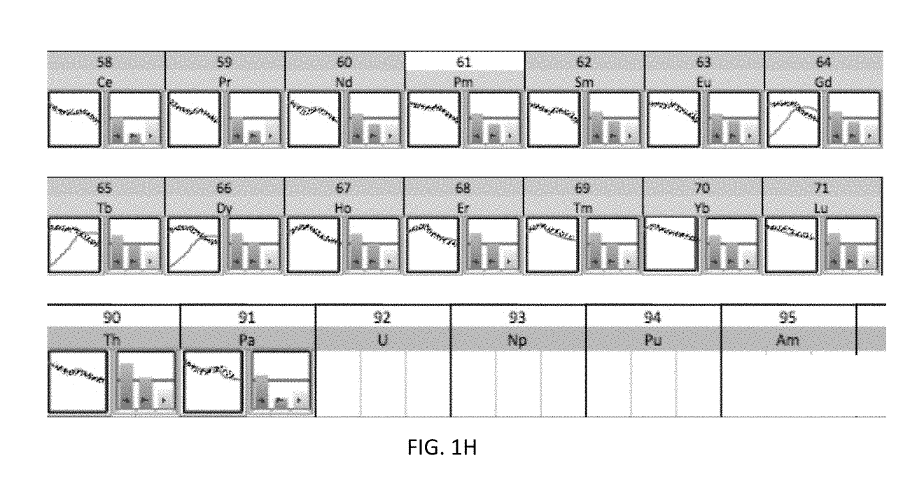

The suitability of a particular metal component depends on the energy of the photon (EUV) or electron (E-beam) that impinges the metal. FIGS. 1A through 1H displays the periodic table showing line graphs of elastic (blue line) and inelastic (red line) electron scattering cross sections associated with each element of the table, for exposures less than 100 eV, with the center line of the graph being 30 eV. Additionally, a bar chart showing the photoabsorption cross section of each element measure at an EUV exposure of 13.5 nm wavelength. The horizontal lines of the bar graphs indicate relative amount of absorption.

It is believed that metals that exhibit at least one of high photoabsorption cross section, median to high inelastic electron scattering profile, and low to median elastic electron scattering will produce the highest photosensitivity when used as a component in photoresists. For example, as can be seen from the chart, tin exhibits a high photoabsorption cross section, median to high inelastic electron scattering and a relatively low elastic electron scattering. Ruthenium exhibits median photoabsorption cross section, with median inelastic electron scattering, at low energy, but high elastic electron scattering. Photoresist compositions that contain tin or ruthenium components show increased photosensitivity.

Suitable metals of the current disclosure are chosen from the periodic table of elements of columns 3 through 17 and rows 3 through 6, which includes Scandium, Titanium, Vanadium, Chromium, Manganese, Iron, Cobalt, Nickel, Copper, Zinc, Gallium, Germanium, Arsenic, Selenium, Bromine, Yttrium, Zirconium, Niobium, Molybdenum, Technetium, Ruthenium, Rhodium, Palladium, Silver, Cadmium, Indium, Tin, Antimony, Tellurium, Iodine, the Lanthanides, Hafnium, Tantalum, Tungsten, Rhenium, Osmium, Iridium, Platinum, Gold, Mercury, Lead, Bismuth, Polonium, and columns 13-17 row 3 which includes Aluminum, Silicon, Phosphorus, Sulfur and Chlorine.

The metals may be neutral or in one or more of its oxidation states, such as, for example, Pt(O), Pt(II) and or Pt(IV).

It has also surprisingly been found that with the addition of metals of the current disclosure the amount of PAG was able to be reduced to get the same or significantly improved photo sensitivity. This may be beneficial in that PAGs can be expensive and can create waste treatment issues.

Metals can be added to the compositions as neutral materials or as their ionic derivative, and in one or more oxidation states, such as, for example, Fe(II) and Fe(III) can be added to one composition. The ionic derivative of the metal can be added as their salts, such salts being well known in the industry, such as, for example, their halides, carbonates, borates, oxides, silicates, oxalates, carboxylates, sulfates, sulfonates, sulfinates, nitrates, nitrites, nitrosates, phosphates, phosphonate, phosphinates, sulfides, hydroxides, arsonates, stilbates and the like.

More than one metal or ionic derivative of a metal or combination can be added to the composition. The metal or ionic derivative of the metal can coordinate to more than one ligand, for example, iron(III) oxalate and iron(III) acetate can be added to the composition at the same time. There is no limit to the number of metals or ionic derivatives of the metal, nor the number of coordinating ligands that can be used as additives to the compositions.

The metals may be added ionic salts in appropriate solvents or as coordination species such as, for example, metal-ligands. It is known that certain ligands are more stable under actinic irradiation such as ebeam and/or EUV radiation, for example, bipyridine is more stable than oxalate. In some embodiments an EUV resist based on a metal complex contains a less stable ligand such as one that undergoes photolysis. In other embodiments the metal complex is stable to the actinic radiation additive and can increase the absorption of the actinic radiation and generate secondary electrons. In such an embodiment more stable ligands can be chosen, so that while the metal absorbs light, and generates photoelectrons, it remains molecularly bound and thus less able to influence other portions of the process, such as, the contamination of the underlying substrate or the photoresist reaction pathway.

Examples include but are not limited to, for example acetylacetonate, bipyridine, ethylenediamine, imidazole, phenanthroline ligands.

There is a plethora of materials that can be used to coordinate metals, also known as ligands. Ligands are generally derived from charge-neutral precursors and are represented by oxides, amines, phosphines, sulfides, carboxylic acid, esters, hydroxys, alkenes, and then like. Denticity refers to the number of times a ligand bonds to a metal through non-contiguous donor sites. Many ligands are capable of binding metal ions through multiple sites, usually because the ligands having lone pairs on more than one atom. Ligands that bind via more than one atom are often termed chelating. A ligand that binds through two sites is classified as bidentate and three sites as tridentate, etc.

Chelating ligands are commonly formed by linking donor groups via organic linkers. Examples include ethylenediamine include A classic bidentate ligand which is derived by the linking of two ammonia groups with an ethylene (—CH2CH2-) linker. A classic example of a polydentate ligand is the hexadentate chelating agent EDTA, which is able to bond through six sites, completely surrounding some metals.

Complexes of polydentate ligands are called chelate complexes. They tend to be more stable than complexes derived from monodentate ligands. When the chelating ligand forms a large ring that at least partially surrounds the central metal and bonds to it, leaving the central atom at the center of a large ring. The more rigid and the higher its denticity, the more stable will be the macrocyclic complex, for example, heme: the iron atom is at the center of a porphyrin macrocycle, being bound to four nitrogen atoms of the tetrapyrrole macrocycle. The very stable dimethylglyoximate complex of nickel is a synthetic macrocycle derived from the anion of dimethylglyoxime.

Photoresists suitable for the current application are well known in the industry such as negative resists based on photoacid generators that cause crosslinking when exposed, thus making them insoluble in developer, while the unexposed materials can be developed away. These resists include, for example, resists that contain materials with acid labile groups. Many examples as disclosed in the literature. Positive working photoresists and chemically amplified photoresists can also be used. In these resists PAGs are used to generate acids which react with acid labile groups resulting in an increase solubility of the composition in suitable developers. Positive photoresists useful for the current disclosure are well known in the industry

While not being held to theory, the metals and/or metal complexes suitable for the current application may not be especially reactive to the actinic radiation, such as Ebeam and/or EUV. They may function as inert generators of secondary electrons resulting from interactions of other species that are in the composition during processing.

The metal or metals may be added to the photoresist composition in the amount of 0.1 wt % to about 25.0 wt % based on solids.

In some embodiments the compositions of the current application include malonates. In other embodiments the compositions of the current application include the adduct of malonates with imine-amine materials. Specific examples of these materials are described in U.S. Pat. No. 9,229,322 and U.S. Pat. No. 9,122,156 both to Robinson et al, both incorporated herein by reference.

PAGs useful for the current disclosure are well known in the industry and include, without limitation, onium salt compounds, such as sulfonium salts, phosphonium salts or iodonium salts, sulfone imide compounds, halogen-containing compounds, sulfone compounds, ester sulfonate compounds, quinonediazide compounds, diazomethane compounds, dicarboximidyl sulfonic acid esters, ylideneaminooxy sulfonic acid esters, sulfanyldiazomethanes, or a mixture thereof.

The methods of using the photoresists of the current disclosure are well known in the art. They include spincoating the resist onto a wafer which has been prepared by a number of processes well known in the art, dried to a predetermined dryness, lithographically exposed to EUV or Ebeam radiation, optionally post exposure baked, and developed in an appropriate known developer to result in a lithographic pattern.

### EXAMPLES

### Examples 1-4

0.2 parts of the adduct of the malonate with imine-amine material prepared in U.S. Pat. No. 9,229,322 to Robinson, et al, were mixed with 2.0 parts of poly[(o-cresyl-glycidyl ether)-co-formaldehyde]and 1.0 parts of triphenylsulfonium tosylate with ethyl lactate to make up a 12.5 g/L concentration. Diphenyliodonium 4-methyl benzenesulfonate was added at 5 wt %. To the admix was added a 0%, 1% 2% and 3% by volume solution of tin chloride solution, 10 g/L in ethyl lactate. The composition was spin-coated onto a silicon wafer at 3000 rpm to give a 19 nm film thickness. A post application bake of 105° C. for 5 min was applied. After the desired exposure, a post exposure bake of 90° C. for 3 minute3 was applied. The unexposed areas were removed using n-butyl acetate. Exposures were performed on a EUV interference lithography tool.

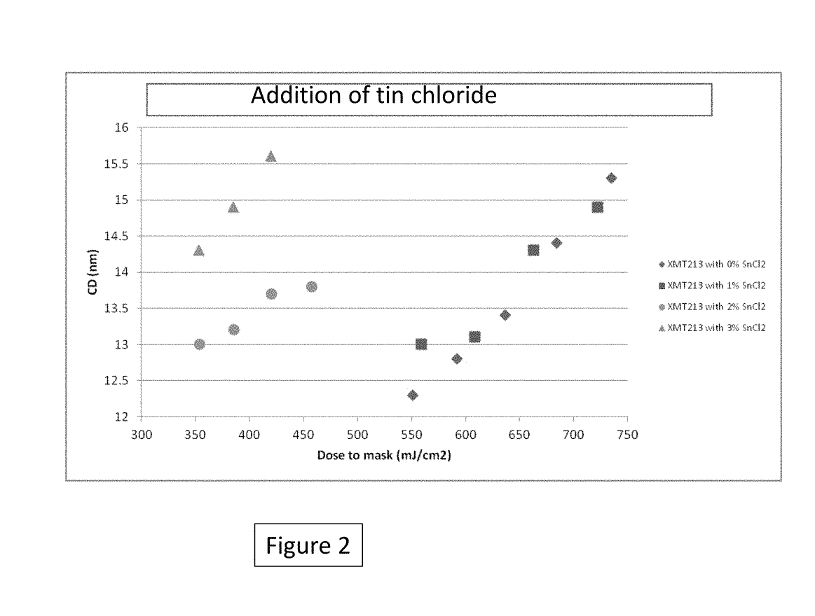

The results are shown in FIG. 2. As can be seen the addition of 2 and 3% by volume of a tin chloride solution significantly increased the photospeed to obtain a given CD or line width. The sample with 1% by wt tin chloride did not show an improvement which may indicate a threshold for improved sensitivity such as overcoming a level of electron elasticity.

### Example 5

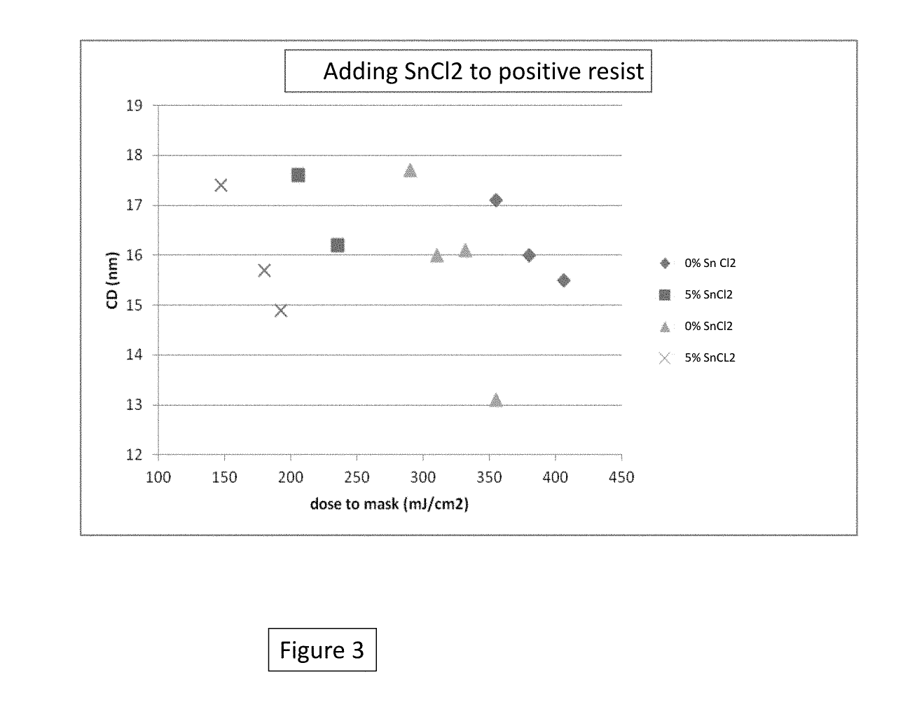

5% tin chloride in a 10 g/L solution in ethyl lactate was added to 2 different proprietary commercial positive working photoresist and processed according to the manufacture's direction, including development with 0.26 N TMAH. As can be seen from FIG. 3 the addition of 5% SnCl2 to the resists significantly increased the photosensitivity of the resist.

### Example 6-8

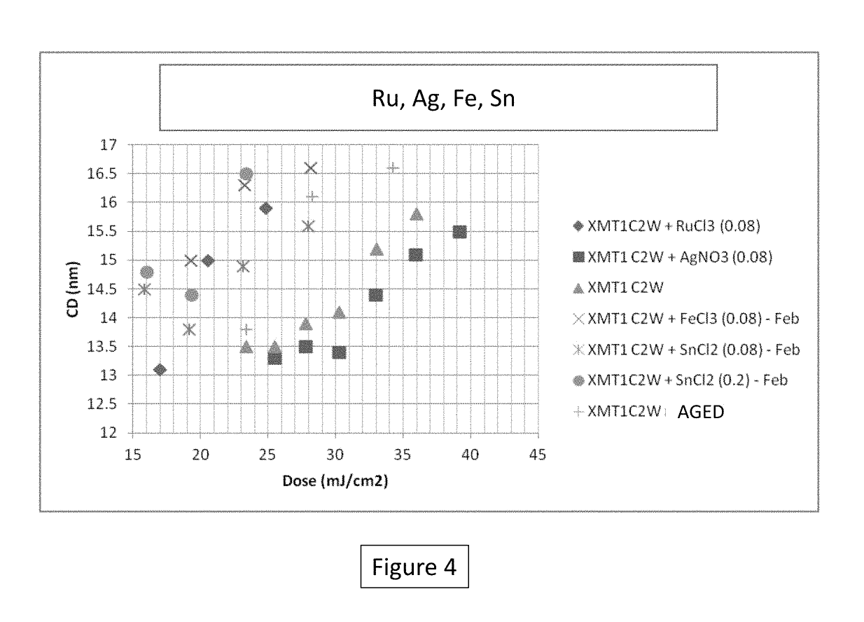

The process of experiment 1 was repeated using 3% ruthenium chloride, 3% silver nitrate added as a water solution due to solubility restrictions, and iron (III) chloride. The results are shown in FIG. 4. As can be seen aging the photoresist can increase the photo sensitivity of the resist, however adding FeCl3 or RuCl3 significantly increase the photo sensitivity of the resist. Note that silver did not improve the photo sensitivity which may be due to the fact that it was added as water solution, such water not having a beneficial effect on the resist. When tin chloride was added as a water solution, the sensitivity was significantly deceased (not shown).

### Example 9-10

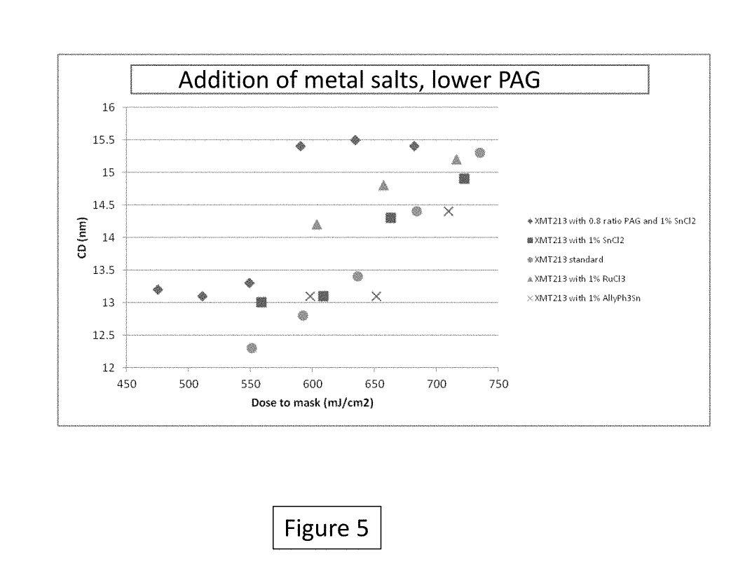

The process of example 1 was repeated using 1% AllylPh₃Sn or 1% Sn Cl₂ while reducing the amount of PAG to 80% of the original formula. As can be seen from FIG. 5, the addition of the tetracoordinate tin organometallic did not improve the photo sensitivity. However also in FIG. 5 it can be seen that with the addition of 1% tin chloride in combination with a decrease in PAG level a significant increase in photosensitivity results. As previously shown the inclusion of % tin chloride did not have an effect on photo sensitivity. This further indicates the synergistic effect that metals of the current disclosure have with PAG in photoresists.

We claim:

1) A photoresist composition comprising at least one metal component wherein the metal component exhibits high EUV photoabsorption cross-section, median to high inelastic electron scattering and low to median elastic scattering coefficients.

2) The composition of claim 1, wherein the at least one metal is chosen from the periodic table of elements of columns 3 through 17 and rows 3 through 6, which includes Scandium, Titanium, Vanadium, Chromium, Manganese, Iron, Cobalt, Nickel, Copper, Zinc, Gallium, Germanium, Arsenic, Selenium, Bromine, Yttrium, Zirconium, Niobium, Molybdenum, Technetium, Ruthenium, Rhodium, Palladium, Silver, Cadmium, Indium, Tin, Antimony, Tellurium, Iodine, the Lanthanides, Hafnium, Tantalum, Tungsten, Rhenium, Osmium, Iridium, Platinum, Gold, Mercury, Lead, Bismuth, Polonium, and columns 13-17 row 3 which includes Aluminum, Silicon, Phosphorus, Sulfur and Chlorine.

3) The composition of claim 2, wherein the at least one metal comprises a metal salt.

4) The composition of claim 2, wherein the at least one metal comprises a coordinated complex.

5) The composition of claim 2, wherein the at least one metal comprises a metal containing ligand.

6) The composition of claim 2, wherein the at least one metal salt comprises an oligomeric or a polymeric ligand.

7) The composition of claim 2, wherein the photoresist composition comprises a negative working photoresist.

8) The composition of claim 2, wherein the photoresist composition comprises a positive working photoresist.

9) The composition of claim 2, wherein the photoresist has sensitivity to radiation comprising EUV radiation.

10) The composition of claim 2, wherein the photoresist has sensitivity to e-beam radiation.

11) The composition of claim 2, wherein the at least one metal comprises at least one EUV stable complexing material.

12) The composition of claim 2, wherein the at least one metal complex comprises at least one EUV unstable complexing material.

13) The composition of claim 2, further comprising a photoacid generator.

14) The composition of claim 2, further comprising at least one of a malonate, a malonate-imine adduct or a malonate-amine-imide adduct.

15) The composition of claim 2, further comprising one or more of polymers, oligomers, crosslinkers, materials with acid labile groups, materials that react with acids, solvent, acid scavengers, colorants, wetting agents, rheological agents, antifoams, fullerenes, fullerene derivatives.

16) The composition of claim 2, wherein the metal is present in the photoresist from about 0.01% wt/wt to about 25% wt/wt.

17) Methods for improving the sensitivity of a photolithographic process comprising:
a. applying the photoresist of claim 2 and removing at least 90% of solvent,
b. exposing the applied photoresist to actinic radiation or E-beam radiation and,
c. removing desired areas using a developer.
